(19) United States
(12) Patent Application Publication
(10) Pub. No.: US 2014/0209361 A1
(43) Pub. Date: Jul. 31, 2014

(54) WIRING BOARD AND METHOD FOR MANUFACTURING THE SAME

(71) Applicant: KYOCERA SLC Technologies Corporation, Yasu-shi (JP)

(72) Inventors: Makoto NAKAI, Hikone-shi (JP); Takashi KATO, Yasu-shi (JP)

(73) Assignee: KYOCERA SLC Technologies Corporation, Yasu-shi (JP)

(21) Appl. No.: 14/151,374

(22) Filed: Jan. 9, 2014

(30) Foreign Application Priority Data
Jan. 31, 2013 (JP) 2013-016482

(51) Int. Cl. H05K 1/11; H05K 3/00

(52) U.S. Cl. CPC H05K 1/115; H05K 3/0026
USPC 174/257; 264/400

(57) ABSTRACT

A wiring board according to the present invention has an insulating board 1 including a land conductor layer 14 on a surface thereof; an insulating layer 5 formed on the insulating board 1; a via hole 6 extending from an upper surface of the insulating layer 5 to the land conductor layer 14; a via conductor 7 formed in the via hole 6 and formed of a plated metal layer; and a wiring conductor 3b formed on the via conductor 7 and electrically connected to the via conductor 7, wherein the via hole 6 is provided with a protruding portion 8a formed of copper foil and protruding from a periphery of an opening of the via hole 6 toward a center of the opening.

### BACKGROUND OF THE INVENTION

1. Field of the Invention

The present invention relates to a wiring board having high-density wiring and a manufacturing method thereof.

2. Description of Related Art

Conventionally, as illustrated in FIG. 3, a wiring board B or the like chiefly structured of an insulating board 21, an insulating layers 25, and a solder resist layer 30 is exemplified as a wiring board for mounting thereon a semiconductor element such as a semiconductor integrated circuit element.

The insulating board 21 has a plurality of through-holes 22 formed from an upper surface through to a bottom surface thereof. A plurality of wiring conductors 23a are formed on the upper and lower surfaces of the insulating board 21. Each of the through-holes 22 is filled with a through-hole conductor 24. The wiring conductors 23a on the upper and lower surfaces of the insulating board 21 are electrically connected to each other by the through-hole conductor 24.

The insulating layers 25 are adhered to the upper and lower surfaces of the insulating board 21. A plurality of wiring conductors 23b are formed on a surface of the insulating layer 25. Further, via holes 26 each of which including a part of the wiring conductor 23a as a bottom surface thereof are formed in the insulating layer 25. Each of the via holes 26 is filled with a via conductor 27. The wiring conductor 23a formed on the insulating board 21 and the wiring conductor 23b formed on the insulating layer 25 are electrically connected to each other through the via conductor 27. The wiring conductor 23b and the via conductor 27 are formed integrally with each other. Solder resist layers 30 are individually adhered to the insulating layers 25 formed on the upper and lower sides of the insulating board 21. The solder resist layers 30 have opening portions 30a and 30b through which a part of the wiring conductor 23b is exposed, and cover a remaining portion of the wiring conductor 23b.

The part of the wiring conductor 23b exposed through the opening portion 30a on an upper surface side functions as a semiconductor element connection pad 31 for connecting to an electrode T of a semiconductor element S. The part of the wiring conductor 23b exposed through the opening portion 30b on a lower surface side functions as an external connection pad 32 for connecting to an external electric circuit board. The semiconductor element S is electrically connected to the external electric circuit board through the wiring conductors 23a and 23b, the through-hole conductor 24, and the via conductor 27 by connecting the electrode T of the semiconductor element S to the semiconductor element connection pad 31 through solder, and by connecting the external connection pad 32 to a wiring conductor of the external electric circuit board through solder. Therefore, signals are transmitted and received between the external electric circuit board and the semiconductor element S, and the semiconductor element S operates.

Incidentally, miniaturization of electronic devices represented by a portable game machine, portable communication device, and the like has been promoted in recent years, and this situation demands miniaturization of the wiring board in which the semiconductor element S used for such device is mounted. To respond to this demand, reducing a diameter of the via conductor 27 and thinning of the wiring conductor 23b are also promoted. As a result, a contact area between the via conductor 27 and the via hole 26 or between the wiring conductor 23b and the insulating layer 25 is also reduced. For this reason, an adhesion strength of the via conductor 27 or the wiring conductor 23b is reduced, which may cause a part of the via conductor 27 or the wiring conductor 23b to be separated from the via hole 26 and the vicinity thereof due to a stress caused by a thermal history such as heat generation when the semiconductor element S operates and cooling when the semiconductor element S stops operating. As a result, it may be possible that the semiconductor element S cannot be operated in a stable manner.

For example, Japanese Unexamined Patent Application Publication No. 10-322021 describes a build-up board having a blind via hole which has a small diameter and a relatively high dimensional accuracy for high densification. However, this build-up board has a small contact area between the hole and through-hole connection, and therefore the through-hole connection tends to be separated.

### BRIEF SUMMARY OF THE INVENTION

It is an object of the present invention to provide a wiring board which can be miniaturized and arranged to have high-density wiring, and in which a via conductor and a wiring conductor are hardly separated from a via hole, therefore connection reliability is excellent, and a semiconductor element operates in a stable manner.

A wiring board according to the present invention has an insulating board including a land conductor layer on a surface thereof; an insulating layer formed on the insulating board; a via hole reaching the land conductor layer from an upper surface of the insulating layer; a via conductor formed in the via hole and formed of a plated metal layer; and a wiring conductor formed on the via conductor and electrically connected to the via conductor, wherein the via hole is provided with a protruding portion formed of copper foil and protruding from a periphery of an opening of the via hole toward a center of the opening.

A method for manufacturing a wiring board according to the present invention includes the steps of sequentially laminating an insulating layer and copper foil on an insulating board including a land conductor layer on a surface thereof; forming a via hole reaching the land conductor layer from an upper surface of the copper foil such that the via hole is provided with a protruding portion formed of the copper foil and protruding from a periphery of an opening of the via hole toward a center of the opening; forming, on the copper foil, a plating resist layer including an opening portion for exposing the via hole and a periphery thereof; forming a via conductor formed of a plated metal layer in the via hole and forming a wiring conductor in the opening portion of the plating resist layer; and removing the plating resist layer and the copper foil in a portion covered with the plating resist layer.

According to the wiring board of the present invention, the via hole is provided with the protruding portion formed of copper foil and protruding from the periphery of the opening of the via hole toward the center of the opening. Accordingly, a contact area of the plated metal layer in the via hole increases, and therefore adherence strengths of the via conductor and the wiring conductor are improved. Therefore, it is possible to suppress separation of parts of the via conductor and the wiring conductor from the via hole and the vicinity thereof due to a stress caused by, for example, a thermal history. As a result, the wiring board according to the present invention can transmit a signal to a semiconductor element in a stable manner, the semiconductor element operates with stability, and miniaturization and high-density wiring are made possible.

According to the method for manufacturing a wiring board of the present invention, the via hole is provided with the protruding portion formed of copper foil and protruding from the periphery of the opening of the via hole toward the center of the opening. Accordingly, in the resultant wiring board, a contact area of the plated metal layer in the via hole increases, and the adherence strength of the via conductor and the wiring conductor is improved. Therefore, it is possible to suppress separation of parts of the via conductor and the wiring conductor from the via hole and the vicinity thereof due to the stress caused by the thermal history. As a result, it is possible to provide the wiring board in which a signal can be transmitted to a semiconductor element in a stable manner, the semiconductor element operates with stability, and miniaturization and high-density wiring are made possible.

### BRIEF DESCRIPTION OF THE DRAWINGS

FIG. 1 is a schematic cross sectional view illustrating an embodiment of a wiring board according to the present invention.

FIGS. 2(a) to (j) are schematic cross sectional views each illustrating an embodiment of a method for manufacturing a wiring board according to the present invention.

FIG. 3 is a schematic cross sectional view illustrating one example of a conventional wiring board.

### DETAILED DESCRIPTION OF PREFERRED EMBODIMENTS

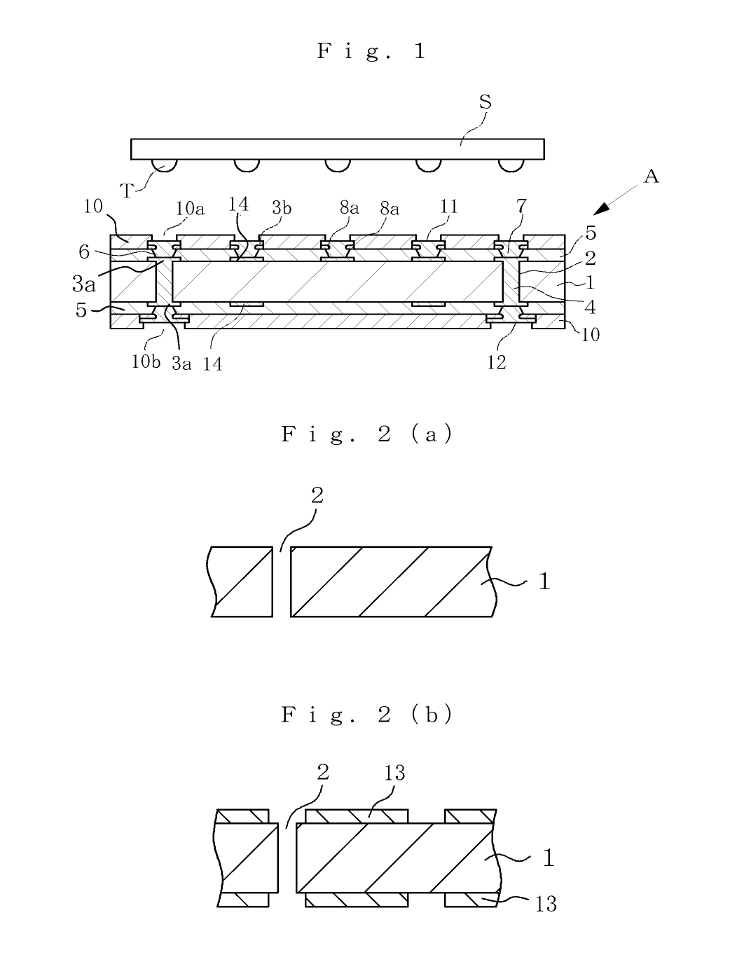

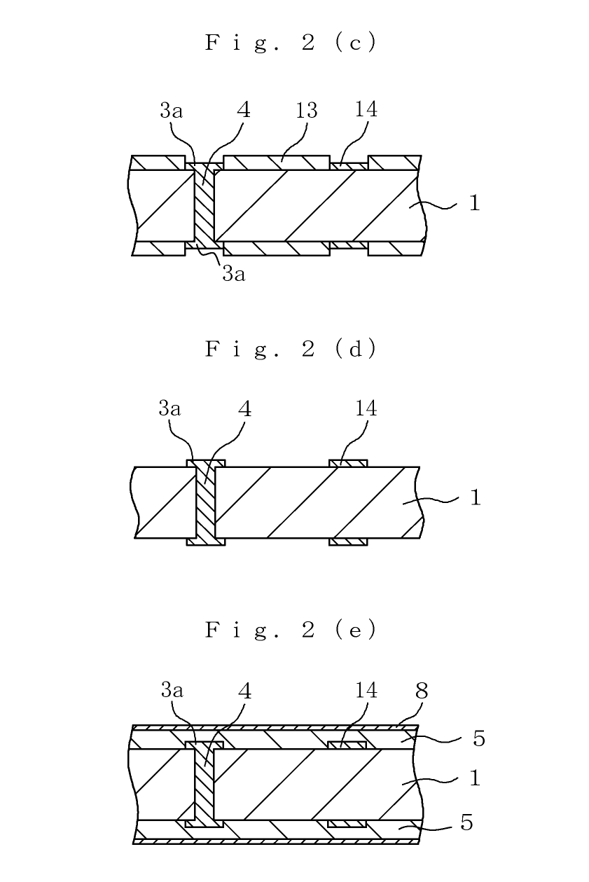

An embodiment of a wiring board according to the present invention will be described with reference to FIG. 1. As illustrated in FIG. 1, a wiring board A according to this example is chiefly structured of an insulating board 1, insulating layers 5, and solder resist layers 10.

The insulating board 1 has a plurality of through-holes 2 formed from an upper surface to a bottom surface thereof. A plurality of wiring conductors 3a are formed on upper and lower surfaces of the insulating board 1. A part of the wiring conductor 3a functions as a land conductor layer 14. Each of the through-holes 2 is filled with a through-hole conductor 4. The wiring conductors 3a on the upper and lower surfaces of the insulating board 1 are electrically connected to each other through the through-hole conductor 4. The insulating board 1 is made of an electric insulating material obtained by impregnating glass cloth with a thermosetting resin such an epoxy resin or a bismaleimide triazine resin. A thickness of the insulating board 1 is about 40 to 300 μm. The wiring conductor 3a is made of a high conductive metal such as a copper plated metal layer, and is preferably formed integrally with the through-hole conductor 4.

The insulating layers 5 are individually adhered to the upper and lower surfaces of the insulating board 1. A plurality of wiring conductors 3b are formed on a surface of each of the insulating layers 5. In addition, via holes 6 each of which including a part of the wiring conductor 3a (land conductor layer 14) as a bottom surface thereof is formed in the insulating layer 5. The via holes 6 are filled with a via conductor 7. The wiring conductor 3a (land conductor layer 14) formed on the insulating board 1 and the wiring conductor 3b formed on the surface of the insulating layer 5 are electrically connected to each other through the via conductor 7. The insulating layer 5 is made of an electric insulating material containing a thermosetting resin such as an epoxy resin or a polyimide resin.

The via hole 6 is provided with protruding portions 8a formed of copper foil and protruding from a peripheral portion of the opening of the via hole 6 toward a center portion of the opening. Each of the protruding portions 8a protrudes from the peripheral portion of the opening of the via hole 6 toward the center portion of the opening by preferably an amount of about 3 to 15 μm. If it is smaller than 3 μm, the adhesion strength of the via conductor 7 and the wiring conductor 3b may become insufficient, and if it is larger than 15 μm, deposition of a metal plating layer in the via hole 6 becomes difficult.

The via conductor 7 is formed of a metal layer such as a copper plated metal layer, and is formed in the via hole 6. A diameter of the via hole 6 is about 50 to 80 μm. The wiring conductor 3b is adhered to the via conductor 7 and the protruding portion 8a. The wiring conductor 3b is formed of a plated metal layer such as a copper plated metal layer, and preferably is formed integrally with the via conductor 7. By integrally forming the wiring conductor 3b and the via conductor 7 together, the number of joints of the plated metal layer is reduced, and therefore the plated metal layer becomes difficult to be separated. As a result, the adherence strength of the via conductor 7 in the via hole 6 and the wiring conductor 3b is further improved.

The solder resist layer 10 is adhered to a surface of the insulating layer 5. The solder resist layer 10 has opening portions 10a and 10b which expose a part of each of the wiring conductors 3b. The solder resist layer 10 is made of an electric insulating material obtained by curing a thermosetting resin having photosensitivity such as an acrylic modified epoxy resin, and protects a covering portion against an external environment.

A part of the wiring conductor 3b exposed from the opening portion 10a on one of the surfaces functions as a semiconductor element connection pad 11 for connecting to an electrode T of a semiconductor element S. A part of the wiring conductor 3b exposed from the opening portion 10b on the other of the surfaces functions as an external connection pad 12 for connecting to an external electric circuit board. By connecting the electrode T of the semiconductor element S to the semiconductor element connection pad 11 through solder, and by connecting the external connection pad 12 to a wiring conductor of the external electric circuit board through solder, the semiconductor element S is electrically connected to the external electric circuit board through the wiring conductors 3a and 3b, the through-hole conductor 4, and the via conductor 7. Therefore, signals are transmitted and received between the external electric circuit board and the semiconductor element S, and the semiconductor element S operates.

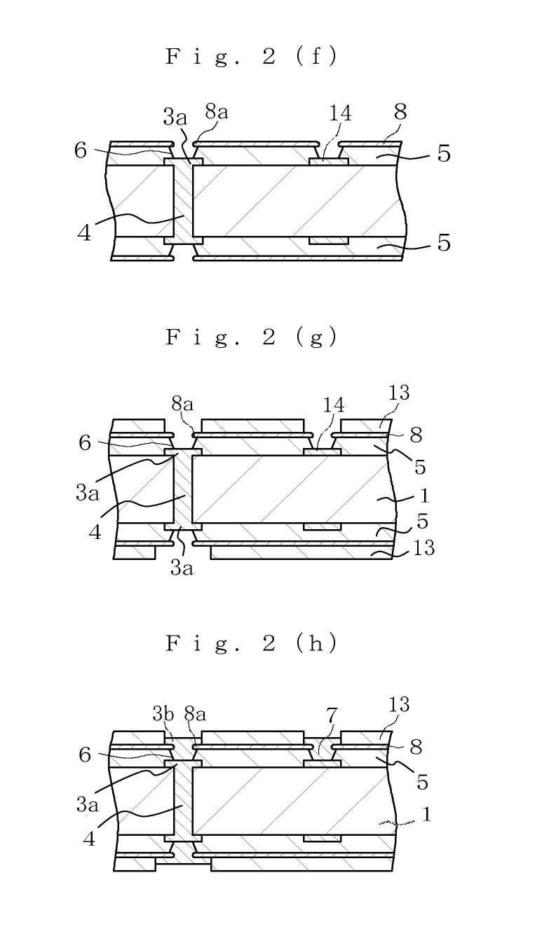

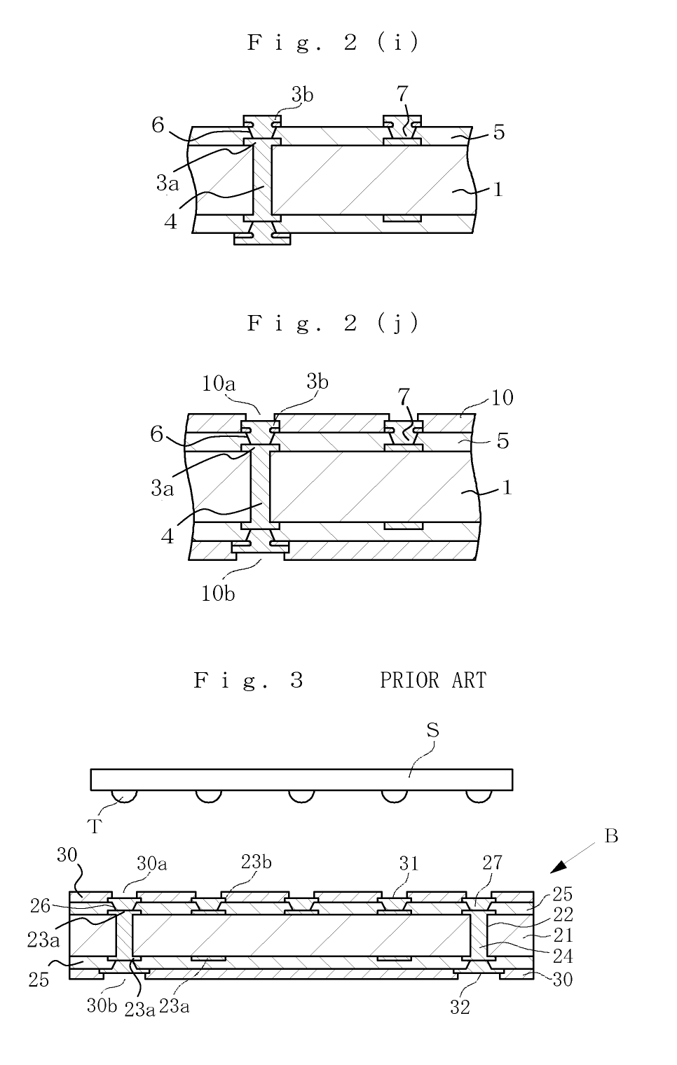

Next, an embodiment of a method for manufacturing a wiring board according to the present invention will be described with reference to FIG. 2. It should be noted that, in FIG. 2, an identical portion of the wiring board A described with reference to FIG. 1 is identified by an identical reference character, and the detailed description thereof will not be repeated.

As illustrated in FIG. 2(a), an insulating board 1 in which a through-hole 2 is formed is prepared. The insulating board 1 is made of an electric insulating material obtained by impregnating glass cloth with a thermosetting resin such an epoxy resin or a bismaleimide triazine resin. A thickness of the insulating board 1 is about 40 to 300 μm. The through-hole 2 is formed by, for example, a drill, laser, or blasting. A diameter of the through-hole 2 is about 50 to 300 μm.

Next, as illustrated in FIG. 2(b), an electroless plating layer (not illustrated) is adhered to a surface of the insulating board 1. Thereafter, plating resists 13 having opening portions for exposing the through-hole 2 and a vicinity thereof, and for exposing a position for forming a land conductor layer 14 are formed on upper and lower surfaces of the insulating board 1. After the plating resists 13 are formed, as illustrated in FIG. 2(c), a through-hole conductor 4, the land conductor layer 14, and a wiring conductor 3a are formed in the through-hole 2 and on the surface of the insulating board 1 which expose from the plating resists 13. These are formed by employing an electrolytic plating method, and by depositing a plated metal layer such as a copper plated metal layer.

Next, as illustrated in FIG. 2(d), the plating resists 13 are separated and removed, and the electroless plating layer is removed, so that the insulating board 1 having the through-hole conductor 4, the land conductor layer 14, and the wiring conductor 3a is formed. As illustrated in FIG. 2(e), after an insulating layer 5 and copper foil 8 are sequentially laminated on the upper and lower surfaces of the insulating board 1, they are adhered to the insulating board 1 by applying hot press. The insulating layer 5 is made of an electric insulating material containing a thermosetting resin such as an epoxy resin or a polyimide resin. The copper foil 8 has a thickness of about 3 to 18 μm. By roughening a surface of the copper foil 8 in advance as required, energy absorption efficiency of laser light is improved, and the via hole 6 with a homogeneous quality can be formed.

As illustrated in FIG. 2(f), the via hole 6 reaching the land conductor layer 14 from the surface of the copper foil 8 can be formed, for example, by laser. During this process, the via hole 6 is formed to be provided with a protruding portion 8a which protrudes from a peripheral portion of an opening of the via hole 6 toward a center portion of the opening and is formed of the copper foil 8. When the via hole 6 is formed, burrs (not illustrated) of the copper foil 8 adhere onto the surface of the copper foil 8 due to a hole formed by the laser.

Since the diameter of the via hole 6 and the length of the protruding portion 8a are described above, the detailed description thereof will not be repeated. For example, it is preferable that the laser irradiation is carried out in twice to form the protruding portion 8. During such a process, it is preferable that energy of the laser irradiation in a second step be set weaker than that in a first step. By reducing the energy in the second step, the hole of the copper foil 8 is suppressed, and the hole of the insulating layer 5 which can be worked easier than the copper foil 8 is promoted, so that the protruding portion 8a can be formed. The energy of the laser irradiation is preferably about 5 to 20 mJ in the first step and about 2 to 10 mJ in the second step.

After processing by the laser, it is preferable that the burrs of the copper foil 8 caused during formation of the via hole 6 be removed by etching. By removing the burrs, it is possible to strongly adhere to the electroless plating layer (not illustrated) onto the surface of the copper foil 8. During the etching process for removing the burrs, by thinning a thickness of the copper foil 8 to about 1 to 3 μm, it becomes easier to remove the copper foil 8 when the copper foil 8 and the electroless plating layer are removed as described later. Further, by removing smear caused inside the via hole 6 by a desmear treatment, the plated metal layer can be firmly adhered to an inner wall of the via hole 6. As illustrated in FIG. 2(g), after the electroless plating layer (not illustrated) is adhered onto the surface of the copper foil 8, plating resists 13 having opening portions for exposing the via hole 6 and the vicinity thereof is formed on the surface of the copper foil 8.

Next, as illustrated in FIG. 2(h), the plated metal layer is deposited by an electrolytic plating method in the via hole 6 which is exposed from the plating resists 13 and on the copper foil 8. Therefore, the via conductor 7 and the wiring conductor 3b are formed integrally with each other. As the plated metal layer, a copper electroplating layer is preferably used. As illustrated in FIG. 2(i), after the via conductor 7 and the wiring conductor 3b are formed, the plating resists 13 are separated and removed, and the copper foil 8 and the electroless plating layer in a portion covered with the plating resists 13 are removed.

Finally, as illustrated in FIG. 2(j), a solder resist layer 10 having the opening portions 10a and 10b for exposing a part of the wiring conductor 3b is formed on the insulating layer 5 and the wiring conductor 3b. In this way, the wiring board A illustrated in FIG. 1 is formed.

It is to be understood that the present invention is not limited to the embodiments described above, and various modifications, improvements, combinations, and the like can be made thereto without departing from the spirit of the present invention. For example, although the insulating layer 5 has a single layer structure in the embodiments described above, the insulating layer 5 may have a multilayer structure obtained by laminating a plurality of insulating layers made of identical or different electric insulating materials.

What is claimed is:

1. A wiring board comprising:
an insulating board including a land conductor layer on a surface thereof;
an insulating layer formed on the insulating board;
a via hole reaching the land conductor layer from an upper surface of the insulating layer;
a via conductor formed in the via hole and formed of a plated metal layer; and
a wiring conductor formed on the via conductor and electrically connected to the via conductor,
wherein the via hole is provided with a protruding portion formed of copper foil and protruding from a periphery of an opening of the via hole toward a center of the opening.

2. The wiring board according to claim 1,
wherein the protruding portion protrudes from the periphery of the opening of the via hole toward the center of the opening by an amount of 3 to 15 μm.

3. The wiring board according to claim 1,
wherein the via conductor and the wiring conductor are formed integrally with the plated metal layer.

4. A method for manufacturing a wiring board, the method comprising the steps of:
sequentially laminating an insulating layer and copper foil on an insulating board including a land conductor layer on a surface thereof;
forming a via hole reaching the land conductor layer from an upper surface of the copper foil such that the via hole is provided with a protruding portion formed of the copper foil and protruding from a periphery of an opening of the via hole toward a center of the opening;
forming, on the copper foil, a plating resist layer including an opening portion for exposing the via hole and a periphery thereof;
forming a via conductor formed of a plated metal layer in the via hole and forming a wiring conductor in the opening portion of the plating resist layer; and
removing the plating resist layer and the copper foil in a portion covered with the plating resist layer.

5. The method for manufacturing a wiring board according to claim 4 further comprising a step of etching a surface of the copper foil after the step of forming the via hole.

6. The manufacturing method according to claim 4,
wherein the protruding portion protrudes from the periphery of the opening of the via hole toward the center of the opening by an amount of 3 to 15 μm.

7. The manufacturing method according to claim 4,
wherein the via conductor and the wiring conductor are formed integrally with the plated metal layer.

8. The manufacturing method according to claim 4,
wherein the copper foil is roughened.

9. The manufacturing method according to claim 4,
wherein the via hole provided with the protruding portion is formed by laser irradiation.

10. The manufacturing method according to claim 9, wherein
the laser irradiation is divided into two steps, and energy of laser irradiation in a second step is set weaker than that in a first step.
